(19) United States
(12) Patent Application Publication
(10) Pub. No.: US 2025/0349471 A1
(43) Pub. Date: Nov. 13, 2025

(54) NOISE FILTER AND WIRE HARNESS

(71) Applicant: Yazaki Corporation, Tokyo (JP)

(72) Inventor: Satoru GOTOU, Shizuoka (JP)

(73) Assignee: Yazaki Corporation, Tokyo (JP)

(21) Appl. No.: 19/080,146

(22) Filed: Mar. 14, 2025

(30) Foreign Application Priority Data
May 13, 2024 (JP) 2024-077946

(51) Int. Cl. H01G 5/16; B60R 16/02; H01G 5/011; H01G 5/014

(52) U.S. Cl. CPC H01G 5/16; B60R 16/0207; H01G 5/011; H01G 5/014

(57) ABSTRACT

A noise filter includes a first terminal, a second terminal, and a housing accommodating the first terminal and the second terminal. The first terminal includes a mounting portion and an extending portion extending from the mounting portion, and the second terminal includes a mounting portion and an extending portion extending from the mounting portion. The housing houses the first terminal and the second terminal such that the extending portion of the first terminal and the extending portion of the second terminal are arranged side by side with an interval between the extending portion of the first terminal and the extending portion of the second terminal. The housing includes an adjustment mechanism that adjusts the interval between the extending portion of the first terminal and the extending portion of the second terminal.

### CROSS-REFERENCE TO RELATED APPLICATIONS

This application is based on and claims priority under 35 USC 119 from Japanese Patent Application No. 2024-077946 filed on May 13, 2024, the contents of which are incorporated herein by reference.

### TECHNICAL FIELD

The present disclosure relates to a noise filter and a wire harness.

### BACKGROUND ART

Patent Literature 1 discloses a noise filter in which a filter circuit including a noise reduction element such as a capacitor or a coil is interposed between the intermediate connection portion of a first electric wire and the intermediate connection portion of a second electric wire, in which the first electric wire and the second electric wire are sandwiched and pressed in the arrangement direction by a first pressing body and a second pressing body of a housing, and the filter circuit is electrically connected to the intermediate connection portions to reduce the electrical noise. According to this noise filter, the intermediate electric wire that connects the electric wire and the filter circuit can be made unnecessary, and the noise generated in the intermediate electric wire can be reduced.

### CITATION LIST

### Patent Literature

Patent Literature 1: JP2020-48075A

### SUMMARY OF INVENTION

Since the capacitor used as the noise reduction element of the filter circuit has a rated electrostatic capacitance, it is difficult to cope with the noise that deviates from a certain frequency component. In the noise filter including the filter circuit, the use of the noise reduction element such as a capacitor increases the cost.

The present disclosure has been made in view of the above-described circumstances, and an object of the present disclosure is to provide a noise filter and a wire harness capable of adjusting the target frequency of the noise to be reduced while reducing the cost.

The above object of the present disclosure is achieved by the following configuration. A noise filter of the present disclosure includes a first terminal that is fixed to an end portion of a first electric wire, a second terminal that is fixed to an end portion of a second electric wire, and a housing that houses the first terminal and the second terminal. The first terminal includes a mounting portion mounted on a core wire of the first electric wire and an extending portion extending from the mounting portion, the second terminal includes a mounting portion mounted on a core wire of the second electric wire and an extending portion extending from the mounting portion, the housing houses the first terminal and the second terminal such that the extending portion of the first terminal and the extending portion of the second terminal are arranged side by side with an interval between the extending portion of the first terminal and the extending portion of the second terminal, and the housing includes an adjustment mechanism that adjusts the interval between the extending portion of the first terminal and the extending portion of the second terminal.

According to the present disclosure, it is possible to provide a noise filter and a wire harness capable of adjusting the target frequency of the noise to be reduced while reducing the cost.

The present disclosure has been briefly described above. Further, the details of the present disclosure can be clarified by reading a mode (hereinafter, referred to as an “embodiment”) for carrying out the invention to be described below with reference to the accompanying drawings.

### BRIEF DESCRIPTION OF DRAWINGS

FIG. 1 is a perspective view of a noise filter according to a first embodiment;

FIG. 2 is a longitudinal cross-sectional view along the longitudinal direction of the noise filter according to the first embodiment;

FIG. 3 is a cross-sectional view taken along a line III-III in FIG. 2;

FIG. 4 is a transverse cross-sectional view along the longitudinal direction of a noise filter according to a second embodiment;

FIG. 5 is a cross-sectional view taken along a line V-V in FIG. 4;

FIG. 6 is a cross-sectional view taken along a line VI-VI in FIG. 4;

FIG. 7 is a cross-sectional view of a wedge member when a screw member is viewed from the side;

FIG. 8 is a top view of the wedge member;

FIG. 9 is a front view of the wedge member;

FIG. 10 is a transverse cross-sectional view along the longitudinal direction of a noise filter according to a third embodiment; and

FIG. 11 is a cross-sectional view taken along a line XI-XI in FIG. 10.

### DESCRIPTION OF EMBODIMENTS

Specific embodiments of the present disclosure will be described below with reference to the drawings.

### First Embodiment

First, a first embodiment will be described.

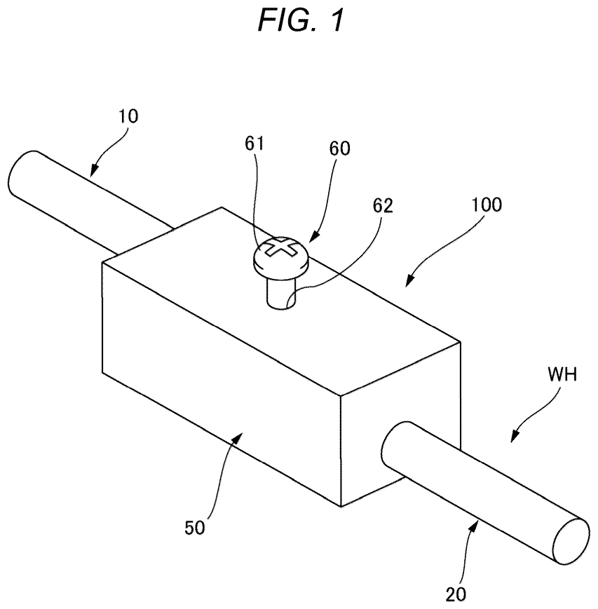

FIG. 1 is a perspective view of a noise filter 100 according to the first embodiment.

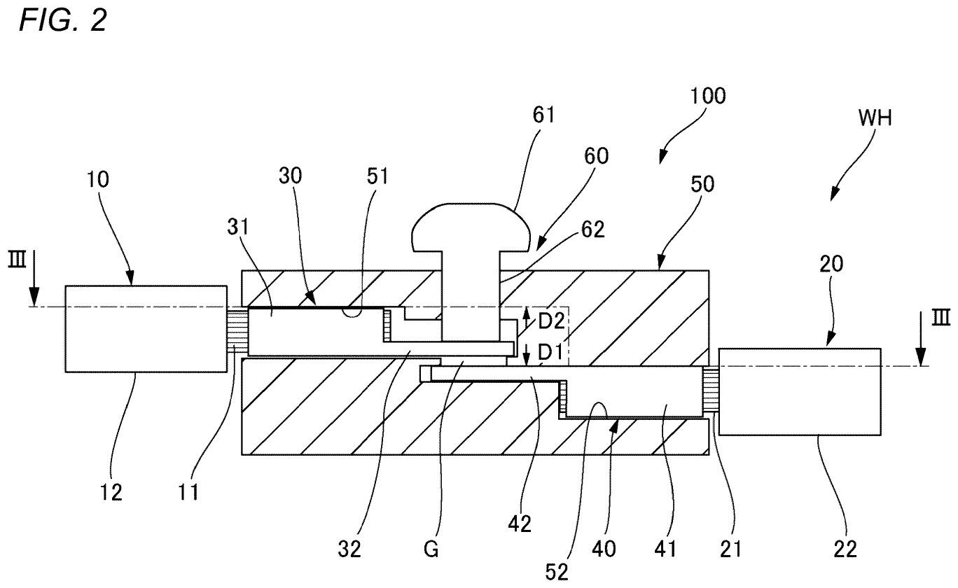

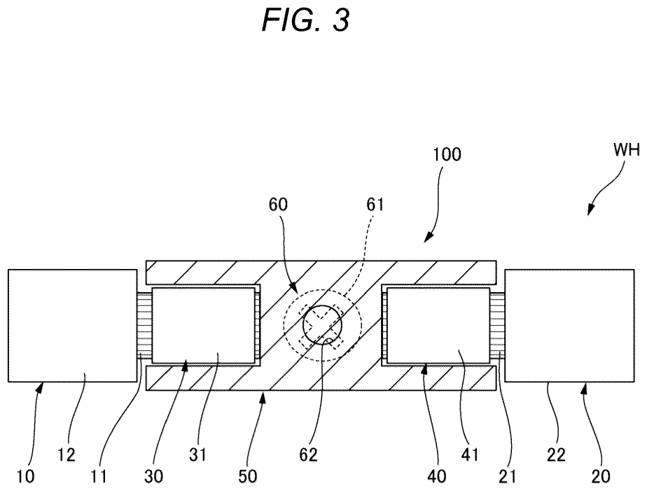

FIG. 2 is a longitudinal cross-sectional view along the longitudinal direction of the noise filter 100 according to the first embodiment. FIG. 3 is a cross-sectional view taken along a line III-III in FIG. 2.

As shown in FIGS. 1 to 3, the noise filter 100 according to the first embodiment is provided in a wire harness WH. The wire harness WH includes a first electric wire 10 and a second electric wire 20, and is routed in a vehicle such as an automobile. For example, the first electric wire 10 is a signal wire or a power wire, and the second electric wire 20 is a ground wire. The first electric wire 10 is an insulated electric wire in which the surrounding of a core wire 11 made of a conductor is covered with a sheath 12. Similarly, the second electric wire 20 is an insulated electric wire in which the surrounding of a core wire 21 made of a conductor is covered with a sheath 22.

The noise filter 100 includes a first terminal 30, a second terminal 40, and a housing 50.

The first terminal 30 is made of, for example, a conductive metal material such as copper or a copper alloy, and is fixed to the end portion of the first electric wire 10. The first terminal 30 includes a mounting portion 31 (corresponding to a first mounting portion) and an extending portion 32 (corresponding to a first extending portion). The first terminal 30 is mounted by, for example, crimping the mounting portion 31 to the exposed core wire 11 at the end portion of the first electric wire 10. Accordingly, the first terminal 30 is electrically connected to the core wire 11 of the first electric wire 10. The extending portion 32 of the first terminal 30 is formed in a plate shape, and extends from the mounting portion 31.

Similarly to the first terminal 30, the second terminal 40 is made of, for example, a conductive metal material such as copper or a copper alloy, and is fixed to the end portion of the second electric wire 20. The second terminal 40 includes a mounting portion 41 (corresponding to a second mounting portion) and an extending portion 42 (corresponding to a second extending portion). The second terminal 40 is mounted by, for example, crimping the mounting portion 41 to the exposed core wire 21 at the end portion of the second electric wire 20. Accordingly, the second terminal 40 is electrically connected to the core wire 21 of the second electric wire 20. The extending portion 42 of the second terminal 40 is formed in a plate shape, and extends from the mounting portion 41.

The housing 50 is made of an insulating resin material. This housing 50 includes a first housing portion 51 and a second housing portion 52. In the housing 50, the first housing portion 51 is provided above the second housing portion 52. The first housing portion 51 is open on one end side of the housing 50, and the second housing portion 52 is open on the other end side of the housing 50. The first housing portion 51 and the second housing portion 52 communicate with each other at the center of the housing 50 in the longitudinal direction.

In the housing 50, the first terminal 30 is inserted and housed in the first housing portion 51, and the second terminal 40 is inserted and housed in the second housing portion 52. The first terminal 30 and the second terminal 40 that are housed in the housing 50 are arranged side by side with a gap G between the extending portions 32 and 42 at the central portion of the housing 50 in the longitudinal direction. In the housing 50, the first housing portion 51 and the second housing portion 52 communicate with each other. A portion where the extending portions 32 and 42 are arranged side by side with the gap G therebetween constitutes a capacitor, and the noise of the high-frequency component of the current that flows through the first electric wire 10 is reduced. That is, in the noise filter 100, the portion where the extending portions 32 and 42 are arranged side by side with the gap G therebetween to form a capacitor serves as a filter that reduces the noise.

The housing 50 includes an adjustment mechanism 60. The adjustment mechanism 60 includes a screw member 61, and the screw member 61 is screwed into a screw hole 62 that is formed in the housing 50. The screw hole 62 is formed in the upper portion at the center of the housing 50 in the longitudinal direction. The distal end of the screw member 61 that is screwed into the screw hole 62 abuts against the extending portion 32 of the first terminal 30 that is housed in the first housing portion 51. The screw member 61 is rotated to advance and retreat along the arrangement direction of the extending portion 32 of the first terminal 30 and the extending portion 42 of the second terminal 40.

In the adjustment mechanism 60, the screw member 61 is screwed, so that the extending portion 32 of the first terminal 30 is pressed and elastically deformed by the distal end of the screw member 61, and is displaced in a direction (an arrow D1 direction in FIG. 2) of approaching the extending portion 42 of the second terminal 40. When the screw member 61 is loosened, the extending portion 32 of the first terminal 30 returns to the original shape, and is displaced in a direction (an arrow D2 direction in FIG. 2) of moving away from the extending portion 42 of the second terminal 40. In this way, in the noise filter 100 including the adjustment mechanism 60, the interval G between the extending portion 32 of the first terminal 30 and the extending portion 42 of the second terminal 40 is adjusted by rotating the screw member 61. Accordingly, the electrostatic capacitance in the filter portion in which the extending portions 32 and 42 are arranged side by side with the gap G therebetween to constitute the capacitor is 10 changed, and the target frequency of the noise to be reduced is adjusted. The target frequency of the noise is adjusted by adjusting the number of rotations and the rotation angle of the screw member 61 while monitoring a measuring instrument such as a spectrum analyzer.

As described above, according to the noise filter 100 in the first embodiment, by arranging the extending portion 32 of the first terminal 30 and the extending portion 42 of the 15 second terminal 40 side by side, the function as a filter for reducing the noise can be achieved at low cost without using a noise reduction element such as a capacitor. Moreover, the target frequency of the noise to be reduced can be adjusted by adjusting the interval G between the extending portion 32 of the first terminal 30 and the extending portion 42 of the second terminal 40 by the adjustment mechanism 60. Specifically, by rotating the screw member 61 of the 20 adjustment mechanism 60, the interval G between the extending portions 32 and 42 can be adjusted, and the target frequency of the noise to be reduced can be easily adjusted.

According to the wire harness WH including the noise filter 100, the function as a filter can be provided at low cost.

An insulating sheet such as an insulator for avoiding a short circuit due to contact of the extending portions 32 and 42 may be provided between the extending portions 32 and 42 that are arranged side by side with the gap G therebetween to constitute a filter portion constituting a capacitor.

### Second Embodiment

Thereafter, a second embodiment will be described. The same components as those 30 of the first embodiment are denoted by the same reference signs, and the description thereof is omitted.

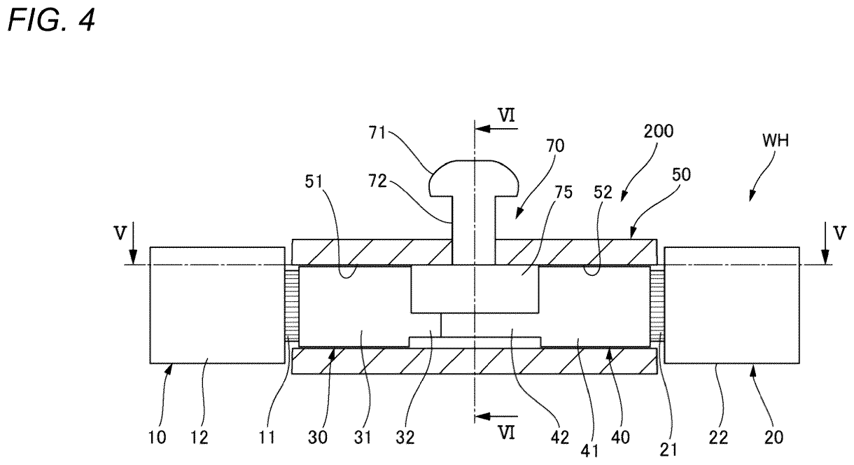

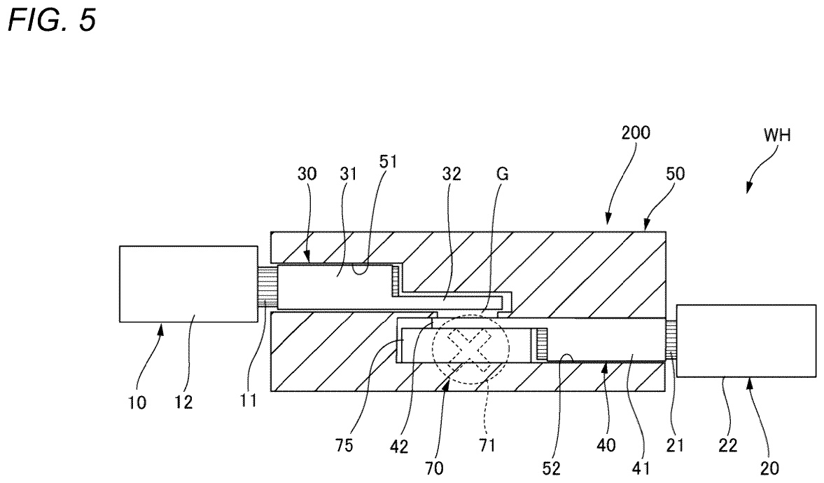

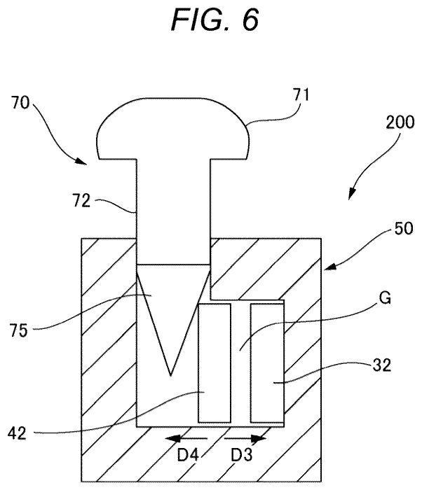

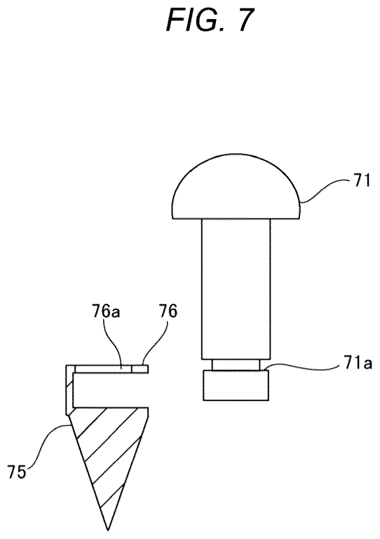

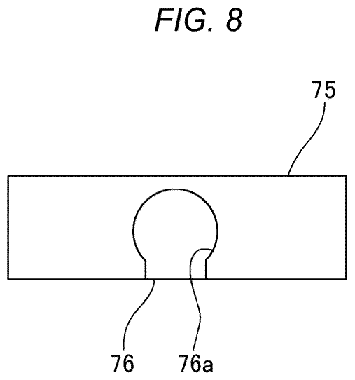

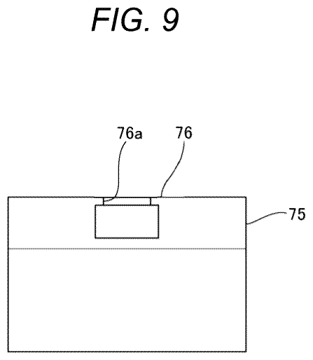

FIG. 4 is a transverse cross-sectional view along the longitudinal direction of a noise filter 200 according to the second embodiment. FIG. 5 is a cross-sectional view taken along a line V-V in FIG. 4. FIG. 6 is a cross-sectional view taken along a line VI-VI in FIG. 4. FIG. 7 is a cross-sectional view of a wedge member 75 when a screw member 71 is viewed from the side. FIG. 8 is a top view of the wedge member 75. FIG. 9 is a front view of the wedge member 75.

As shown in FIGS. 4 to 6, the noise filter 200 according to the second embodiment includes an adjustment mechanism 70. The adjustment mechanism 70 includes the screw member 71 including the wedge member 75. The screw member 71 is screwed into a screw hole 72 that is formed in the housing 50. The screw hole 72 is formed in the side portion at the center of the housing 50 in the longitudinal direction. The wedge member 75 is provided on the side portion of the extending portion 42 of the second terminal 40 in the second housing portion 52 of the housing 50 in a state of being mounted on the distal end of the screw member 71. The screw member 71 is rotated, so that the wedge member 75 is advanced and retracted in a direction orthogonal to the arrangement direction of the extending portion 32 of the first terminal 30 and the extending portion 42 of the second terminal 40.

As shown in FIGS. 7 to 9, the wedge member 75 has a cross-sectional shape that gradually narrows toward the distal end. A locking portion 76 including a locking piece 76a is formed at the rear end portion of the wedge member 75, and the distal end of the screw member 71 is locked to this locking portion 76. The screw member 71 has a locking groove 71a at the distal end thereof, and the locking piece 76a formed on the locking portion 76 of the wedge member 75 is locked to this locking groove 71a. Accordingly, the wedge member 75 is mounted on the distal end of the screw member 71 in a state in which the wedge member 75 can idle with respect to the rotation of the screw member 71.

In the adjustment mechanism 70, when the screw member 71 is screwed, the wedge member 75 is inserted into the side portion of the extending portion 42 of the second terminal 40 in the second housing portion 52. Accordingly, the extending portion 42 of the second terminal 40 is pressed and elastically deformed by the wedge member 75, and is displaced in a direction (an arrow D3 direction in FIG. 6) of approaching the extending portion 32 of the first terminal 30. When the screw member 71 is loosened, the wedge member 75 is pulled out from the side portion of the extending portion 42 of the second terminal 40 in the second housing portion 52. Accordingly, the extending portion 42 of the second terminal 40 returns to the original shape, and is displaced in a direction (an arrow D4 direction in FIG. 6) of moving away from the extending portion 32 of the first terminal 30. In this way, in the noise filter 200 including the adjustment mechanism 70, the gap G between the extending portion 32 of the first terminal 30 and the extending portion 42 of the second terminal 40 is adjusted by rotating the screw member 71 and moving the wedge member 75. Accordingly, the electrostatic capacitance in the filter portion in which the extending portions 32 and 42 are arranged side by side with the gap G therebetween to constitute the capacitor is changed, and the target frequency of the noise to be reduced is adjusted.

In this way, according to the noise filter 200 in the second embodiment, by rotating the screw member 71 of the adjustment mechanism 70 and moving the wedge member 75, the gap G between the extending portions 32 and 42 can be adjusted, and the target frequency of the noise to be reduced can be easily adjusted.

### Third Embodiment

Thereafter, a third embodiment will be described. The same components as those of the first embodiment and the second embodiment are denoted by the same reference signs, and the description thereof is omitted.

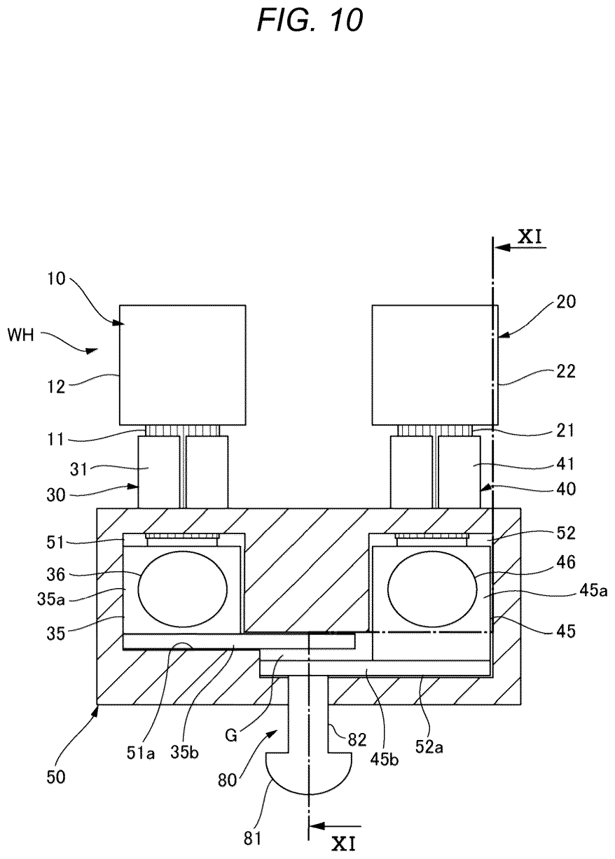

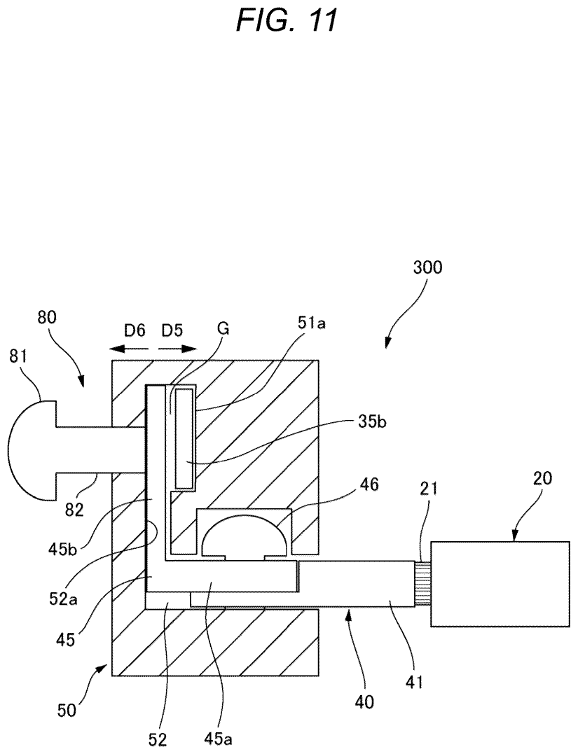

FIG. 10 is a transverse cross-sectional view along the longitudinal direction of a noise filter 300 according to the third embodiment. FIG. 11 is a cross-sectional view taken along a line XI-XI in FIG. 10.

As shown in FIGS. 10 and 11, in the noise filter 300 according to the third embodiment, the first housing portion 51 and the second housing portion 52 are open on one side of the housing 50. The first terminal 30 and the second terminal 40 are inserted and housed in the first housing portion 51 and the second housing portion 52 from the one side of the housing 50. The first housing portion 51 and the second housing portion 52 include bus bar housing portions 51a and 52a, respectively. These bus bar housing portions 51a and 52a extend toward the upper side of the housing 50, and communicate with each other at the central portion of the housing 50 in the longitudinal direction.

In the noise filter 300, the first terminal 30 and the second terminal 40 include bus bars 35 and 45, respectively. The bus bars 35 and 45 are, for example, a plate material of a conductive metal material such as copper or a copper alloy, and are bent in an L shape.

The bus bar 35 includes a fixed portion 35a and an extending portion 35b (corresponding to a third extending portion), and the fixed portion 35a is fixed to the first terminal 30 by a screw 36. Accordingly, the bus bar 35 is electrically connected to the first terminal 30. Similarly, the bus bar 45 includes a fixed portion 45a and an extending portion 45b (corresponding to a third extending portion), and the fixed portion 45a is fixed to the second terminal 40 by a screw 46. Accordingly, the bus bar 45 is electrically connected to the second terminal 40. The extending portion 35b of the bus bar 35 is housed in the bus bar housing portion 51a of the first housing portion 51, and the extending portion 45b of the bus bar 45 is housed in the bus bar housing portion 52a of the second housing portion 52. The extending portions 35b and 45b are arranged side by side in the central portion of the housing 50 in the longitudinal direction. In the housing 50, the bus bar housing portion 51a of the first housing portion 51 and the bus bar housing portion 52a of the second housing portion 52 communicate with each other. A portion where the extending portions 35b and 45b are arranged side by side with the gap G therebetween constitutes a capacitor, and the noise of the high-frequency component of the current that flows through the first electric wire 10 is reduced.

The housing 50 of the noise filter 300 includes an adjustment mechanism 80 including a screw member 81. The screw member 81 is screwed into a screw hole 82 formed on the other side at the center of the housing 50 in the longitudinal direction, and the distal end of the screw member 81 abuts against the extending portion 45b of the bus bar 45. The screw member 81 is rotated to advance and retreat along the arrangement direction of the extending portion 35b of the bus bar 35 and the extending portion 45b of the bus bar 45.

In the adjustment mechanism 80, the screw member 81 is screwed, so that the extending portion 45b of the bus bar 45 connected to the second terminal 40 is pressed and elastically deformed by the distal end of the screw member 81, and is displaced in a direction (an arrow D5 direction in FIG. 11) of approaching the extending portion 35b of the bus bar 35 connected to the first terminal 30. When the screw member 81 is loosened, the extending portion 45 of the bus bar 45 connected to the second terminal 40 returns to the original shape, and is displaced in a direction (an arrow D6 direction in FIG. 11) of moving away from the extending portion 35b of the bus bar 35 connected to the first terminal 30. In this way, in the noise filter 300 including the adjustment mechanism 80, the interval G between the extending portion 35b of the bus bar 35 connected to the first terminal 30 and the extending portion 45b of the bus bar 45 connected to the second terminal 40 is adjusted by rotating the screw member 81. Accordingly, the electrostatic capacitance in the filter portion in which the extending portions 35b and 45b are arranged side by side with the gap G therebetween to constitute the capacitor is changed, and the target frequency of the noise to be reduced is adjusted.

In this way, according to the noise filter 300 in the third embodiment, the bus bars 35 and 45 are connected to the first terminal 30 and the second terminal 40, and the extending portion 35b of the bus bar 35 and the extending portion 45b of the bus bar 45 are arranged side by side, so that the function as a filter for reducing the noise can be achieved.

The present disclosure is not limited to the embodiment described above, and can be appropriately modified, improved, or the like. In addition, the materials, shapes, sizes, numbers, arrangement positions, and the like of the components in the embodiments described above are freely selected and are not limited as long as the present disclosure can be implemented.

Here, the features of the embodiments of the noise filter and the wire harness according to the present disclosure described above are briefly summarized and listed in the following [1] to [5]. [1] A noise filter including:
a first terminal (30) that is fixed to an end portion of a first electric wire (10);
a second terminal (40) that is fixed to an end portion of a second electric wire (20); and
a housing (50) configured to house the first terminal (30) and the second terminal (40),
in which the first terminal (30) includes a mounting portion (31) to be mounted on a core wire (11) of the first electric wire (10) and an extending portion (32) that extends from the mounting portion (31),
the second terminal (40) includes a mounting portion (41) to be mounted on a core wire (21) of the second electric wire (20) and an extending portion (42) that extends from the mounting portion (41),
the housing (50) houses the first terminal (30) and the second terminal (40) such that the extending portion (32) of the first terminal (30) and the extending portion (42) of the second terminal (40) are arranged side by side with an interval (G) between the extending portion (32) of the first terminal (30) and the extending portion (42) of the second terminal (40), and
the housing (50) includes an adjustment mechanism (60, 70, 80) configured to adjust the interval (G) between the extending portion (32) of the first terminal (30) and the extending portion (42) of the second terminal (40).

According to the noise filter having the configuration [1] described above, by arranging the extending portion of the first terminal and the extending portion of the second terminal side by side, the function as a filter for reducing the noise can be achieved at low cost without using a noise reduction element such as a capacitor. Moreover, the target frequency of the noise to be reduced can be adjusted by adjusting the interval between the extending portion of the first terminal and the extending portion of the second terminal by the adjustment mechanism.

[2] The noise filter according to [1] described above,
in which the adjustment mechanism (60) is a screw member (61) that is screwed into a screw hole (62) of the housing (50), and the screw member (61) is rotated to advance or retract, so that one of the extending portions (32) is displaced in a direction of approaching or moving away from the other of the extending portions (42).

According to the noise filter having the configuration [2] described above, by rotating the screw member, the interval between the extending portions can be adjusted, and the target frequency of the noise to be reduced can be easily adjusted.

[3] The noise filter according to [2] described above,
in which the adjustment mechanism (70) includes a wedge member (75) that is assembled to the screw member (71) and that is provided on one side portion of the extending portions (32, 42) arranged side by side, and
the screw member (71) is rotated to advance or retract to move the wedge member (75), so that one of the extending portions (42) is displaced in a direction of approaching or moving away from the other of the extending portions (32).

According to the noise filter having the configuration [3] described above, by rotating the screw member and moving the wedge member, the interval between the extending portions can be adjusted, and the target frequency of the noise to be reduced can be easily adjusted.

[4] The noise filter according to [1] described above,
in which bus bars (35, 45) are electrically connected to the first terminal (30) and the second terminal (40), respectively, and the bus bars (35, 45) are provided with extending portions (35b, 45b) that approach or move away from each other to adjust a gap (G) between the extending portions (35b, 45b) by the adjustment mechanism.

According to the noise filter having the configuration [4] described above, the bus bars are connected to the first terminal and the second terminal, and the extending portions of the bus bars are arranged side by side, so that the function as a filter for reducing the noise can be achieved.

[5] A wire harness including:
the noise filter (100, 200, 300) according to any one of [1] to [4] described above.

According to the wire harness having the configuration [5] described above, it is possible to provide a wire harness having the function as a filter at low cost.

What is claimed is:

1. A noise filter comprising:
a first terminal that is fixed to an end portion of a first electric wire;
a second terminal that is fixed to an end portion of a second electric wire; and
a housing that houses the first terminal and the second terminal, wherein
the first terminal includes a first mounting portion mounted on a core wire of the first electric wire and a first extending portion extending from the first mounting portion,
the second terminal includes a second mounting portion mounted on a core wire of the second electric wire and a second extending portion extending from the second mounting portion,
the housing houses the first terminal and the second terminal such that the first extending portion of the first terminal and the second extending portion of the second terminal are arranged side by side with an interval between the first extending portion of the first terminal and the second extending portion of the second terminal, and
the housing includes an adjustment mechanism that adjusts the interval between the first extending portion of the first terminal and the second extending portion of the second terminal.

2. The noise filter according to claim 1, wherein
the adjustment mechanism is a screw member that is screwed into a screw hole of the housing, and the screw member is rotated to advance or retract, so that the first extending portion is displaced in a direction of approaching or moving away from the second extending portion.

3. The noise filter according to claim 2, wherein
the adjustment mechanism includes a wedge member that is assembled to the screw member and that is provided on one side portion of one of the first or second extending portions arranged side by side, and
the screw member is rotated to advance or retract to move the wedge member, so that the second extending portion is displaced in a direction of approaching or moving away from the first extending portion.

4. The noise filter according to claim 1, wherein
bus bars are electrically connected to the first terminal and the second terminal, respectively, and each of the bus bars includes a third extending portion that approaches or moves away from each other to adjust a gap between the third extending portions by the adjustment mechanism.

5. A wire harness comprising:
the noise filter according to claim 1.
